(19) United States
(12) Patent Application Publication
(10) Pub. No.: US 2009/0026483 A1
(43) Pub. Date: Jan. 29, 2009

(54) HIGH-POWER LED PACKAGE

(75) Inventor: Chin-Sung LIN, Taichung County (TW)

Correspondence Address: BROWDY AND NEIMARK, P.L.L.C.;624 NINTH STREET, NW, SUITE 300, WASHINGTON, DC, 20001-5303, US

(73) Assignee: Tera Autotech Corporation, Taichung Hsien (TW)

(21) Appl. No.: 11/861,993

(22) Filed: Sep. 26, 2007

(30) Foreign Application Priority Data
Jul. 25, 2007 (TW) 96127154

(51) Int. Cl. H01L 33/00

(52) U.S. Cl. 257/99; 257/E33.058

(57) ABSTRACT

A high-power LED package includes a thermally conductive substrate, a plurality of electric contact pins, and at least one high-power LED. The thermally conductive substrate has a circuit board, a metal plate, and a connecting member connected between the circuit board and the metal plate. The substrate is provided with a plurality of through holes running through the circuit board and the metal plate. The electric contact pins are received in the respective through holes and partially extending out of the through holes. The high-power LED is mounted on the metal plate and electrically connected to the circuit board by means of a plurality of metal wires. Therefore, the metal plate having preferable thermal conductivity can effectively dissipate the heat generated by the high-power LED.

### BACKGROUND OF THE INVENTION

1. Field of the Invention

The present invention relates generally to high-power LED packages, and more particularly, to a high-power LED package having higher thermal dissipativity than the prior art.

2. Description of the Related Art

Referring to FIG. 1, a general high-power light emitting diode (LED) package is primarily composed of a substrate 1 and a high-power LED 2. The substrate 1 includes a metal plate 3, an insulated layer 4 disposed on the metal plate 3, and a circuit layer 5 mounted on the insulated layer 4. The high-power LED 2 is mounted on the circuit layer 5 and electrically connected (soldered) with the circuit layer 5 by means of a plurality of metal wires 6, whereby the high-power LED 2 is electrically conducted by the circuit layer 5 for emitting the light.

Although the high-power LED emits brighter light than that of the conventional small LED, it generates higher temperature than the same does. As for the above-mentioned package, the heat generated by the high-power LED 2 can be directly conducted to the circuit layer 5, but the circuit layer 5 must be provided for passing through by electric current to have certain temperature, such that it is difficult for the circuit layer 5 to conduct the heat of the LED 2. The metal plate 3 though has higher thermal conductivity, but the insulated layer is located between the metal plate 3 and the circuit layer 5 and the coefficient of thermal conductivity of the insulated layer 4 is very low, such that it is difficult to conduct the heat of the circuit layer 5 to the metal plate 3 and thus the whole thermal conductivity is low. Under the circumstances, when the heat of the LED 2 cannot be conducted (dissipated) outward to increase the temperature of the same, the brightness of the LED 2 is affected to be decreased. Further, if the temperature of the LED 2 keeps high for a long time, the working life of the LED 2 will be shortened.

In addition, there are other kinds of substrates for LEDs. For example, a ceramic substrate has excellent thermal conductivity and low dielectric constant but it is too expensive to be popularly applied except high-level products. Therefore, the conventional LED package usually has the drawbacks of low thermal dissipativity and high production cost.

Owing to the circuit process, the conventional thermally dissipative substrate also fails to provide a preferable reflective side so that the light reflection of the LED die is not good to cause ineffective utilization of the light emitted by the LED, i.e. it fails to enhance the light utilization efficiency.

### SUMMARY OF THE INVENTION

The primary objective of the present invention is to provide a high-power LED package, which has preferable thermal conductivity to facilitate thermal dissipation thereof.

The secondary objective of the present invention is to provide a high-power LED package, which can enhance brightness of LED.

The foregoing objectives of the present invention are attained by the high-power LED package composed of a thermally conductive substrate, a plurality of electric contact pins, at least one high-power LED, and a cover member. The thermally conductive substrate includes a circuit board, a metal plate, and a connecting member connected between the circuit board and the metal plate. The metal plate is an aluminum plate having high reflectivity and preferable thermally dissipative efficiency. The substrate is provided with a plurality of through holes running through the circuit board and the metal plate. The electric contact pins are received in the respective through holes and partially exposed outside the through holes. The at least one high-power LED is mounted on the metal plate and electrically connected to the circuit board by means of a plurality of metal wires. The cover member is mounted on the metal plate to cover the LED and the wires.

### BRIEF DESCRIPTION OF THE DRAWINGS

FIG. 1 is a sectional view of a conventional high-power LED package.

FIG. 2 is a sectional view of a first preferred embodiment of the present invention.

FIG. 3 is a sectional view of a second preferred embodiment of the present invention.

FIG. 4 is a sectional view of a third preferred embodiment of the present invention.

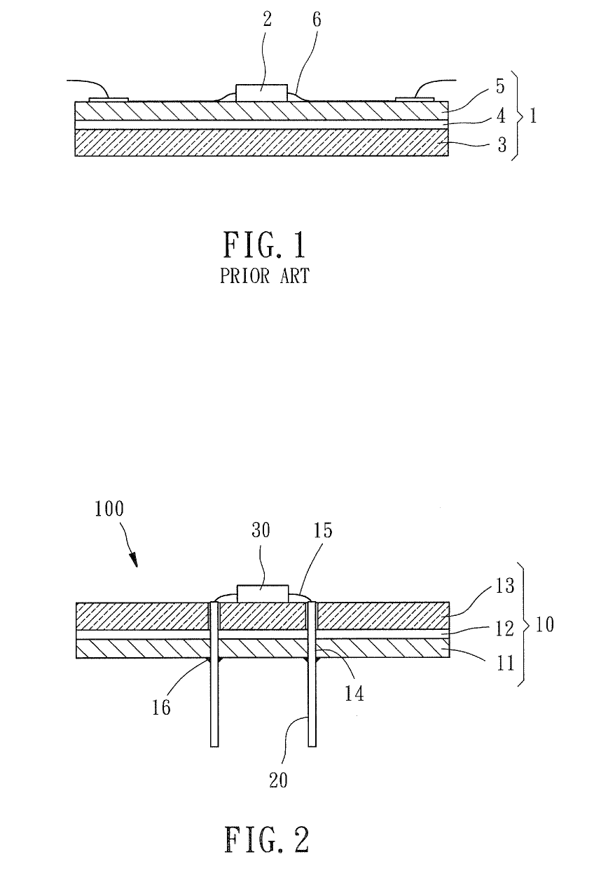

### DETAILED DESCRIPTION OF PREFERRED EMBODIMENTS

Referring to FIG. 2, a high-power LED package 100 constructed according to a first preferred embodiment of the present invention is composed of a thermally conductive substrate 10, a plurality of electric contact pins 20, and a plurality of high-power LEDs 30.

The thermally conductive substrate 10 includes a circuit board 11, a connecting member 12, and a metal plate 13. The metal plate 13 is made of a material having high reflectivity and preferable thermal conductivity, like aluminum, magnesium, cooper, and titanium. In this preferred embodiment, the metal plate 13 is made of aluminum, which has been vacuum-electroplated, and the connecting member 12 is an adhesive having electrically insulating effect. The connecting member 12 is disposed between a top side of the circuit board 11 and a bottom side of the metal plate 13 so as to closely adhesively connect the circuit board 11 and the metal plate 13 and to enable electric insulation between them. A plurality of through holes 14 are formed to run through the metal plate 13 and the circuit board 11 from a top side of the former to a bottom side of the latter.

The electric contact pins 20 are received in the respective through holes 14 and each have one end running out of the through hole 14 and exposed outside the bottom side of the circuit board 11. Tin paste 16 is spread on the bottom side of the electric contact pins 20 to enable the circuit board 11 to be fixedly connected with the electric contact pins 20.

The high-power LEDs 30, in this embodiment, are dies mounted on the top side of the metal plate 13. Metal wires 15 are connected to the LEDs 30 and the electric contact pins 20 located in the through holes 14 by wire bonding for electrical conduction between the LEDs 30 and the electric contact pins 20.

When the parts that the electric contact pins 20 are exposed outside the circuit board 11 is electrically conducted by a power, the high-power LEDs 30 starts to emit light and then the heat generated by the LEDs 30 is directly conducted outward through the metal plate 13 to prevent the LEDs 30 from generating overhigh temperature and to further enhance the working life of the LEDs 30.

In addition, the metal plate 13 is an aluminum plate having high reflectivity, such that the metal plate 13 can reflect the light emitted by the LEDs 30 to enhance the brightness and the light utilization efficiency.

In light of the above, the present invention directly utilizes the aluminum substrate for a medium of thermal conduction to have remarkably greater thermal conductivity than the prior art does. Because the LED package of the present invention is made of low-cost material and by simple process, the cost saving of the present invention can reach 60% relative to the prior art. The result of experiments demonstrates that the thermal resistance of the thermally conductive substrate of the present invention under the test as the power of the LEDs is 2.196 W is 1.23° C./W. Therefore, such substrate is very applicable to the high-power LED package because it is not only highly thermally conductive but also applicable to the aluminum substrates having different reflectivity for different applications. Particularly, after experimental test, the aluminum plate having high reflectivity can more effectively enhance the light utilization efficiency up to 30% than the common aluminum plate done by anodizing surface treatment can.

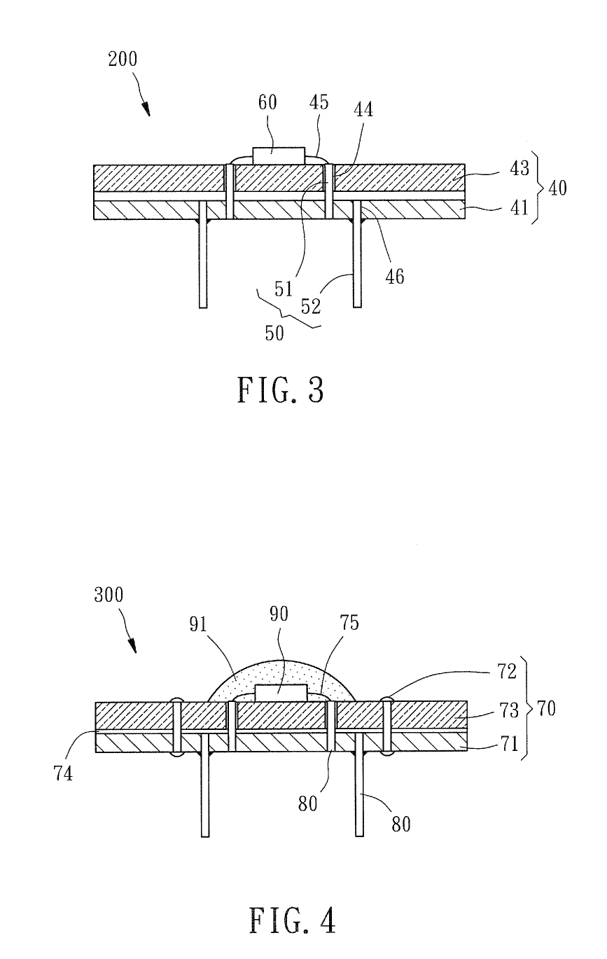

Referring to FIG. 3, a high-power LED package 200 constructed according to a second preferred embodiment of the present invention is similar to that of the first embodiment, having a thermally conductive substrate 40, a plurality of electric contact pins 50, and a plurality of high-power LEDs 60. The second embodiment is different from the first embodiment as recited below.

The thermally conductive substrate 40 includes a plurality of first through holes 40, which run through the metal plate 43 and the circuit board 41 from a top side of the former to a bottom side of the latter, and a plurality of second through holes 46, which run through a top side and the bottom side of the circuit board 41. The first and second through holes 44 and 46 does not correspond to each other in position. Each of the electric contact pins 50 includes a first contact portion 51 and a second contact portion 52. The first contact portions 51 are received in the respective first through holes 44 and electrically connected with the LEDs 60 by means of the metal wires 45. The second contact portions 52 are located in the respective second through holes 46, each having one end running out of the through hole 46 and exposed outside the bottom side of the circuit board 41. The second contact portions 52 are electrically connected with the first contact portions 51 by means of, in this embodiment, the circuit designed in the circuit board, for plugging in an external power source for electric conduction of the LEDs 60.

In light of the above, the first and second contact portions 51 and 52 are differently located for electrical connection with the LEDs 60 and the external power source in the second embodiment, and the second contact portion 52 is compatible in configuration with a power socket (not shown) provided for plugging with the LED package. In other words, the circuit board 41 is formed as an imaginary space converter for circuit to enable corresponding modifications of the second contact portions 52 to match various kinds of sockets (not shown) provided for plugging with the LED package in configuration. Therefore, the applications of the present invention are much comprehensive.

Referring to FIG. 4, a high-power LED package 300 constructed according to a third preferred embodiment of the present invention is similar to that of the second embodiment, having a thermally conductive substrate 70, a plurality of electric contact pins 80, and a plurality of high-power LEDs 90. The third embodiment is different from the second embodiment as recited below.

The connecting member 72 of the thermally conductive substrate 70 is composed of a plurality of rivets in this embodiment and fixedly connected between the circuit board 71 and the metal plate 73. In this embodiment, an insulated layer 74 is disposed between the circuit board 71 and the metal plate 73 to avoid electric interference between the metal plate 73 and the circuit board 71. In addition, the high-power LED package 300 further includes a cover member 91 mounted on the metal plate 73 for covering the LEDs 90 and the metal wires 75 to avoid external contamination. In this embodiment, the cover member 91 is a colloid made of silicone.

In conclusion, the thermally conductive effect of the present invention is apparently enhanced with respect to the prior art using the thermally conductive substrate. Further, the material that the present invention is made is low in production cost and is made by simple process so that it is much applicable to the high-power LED. Besides, the present invention allows different reflectivities of the metal plates to be applicable to different applications.

Although the present invention has been described with respect to specific preferred embodiments thereof, it is no way limited to the details of the illustrated structures but changes and modifications may be made within the scope of the appended claims.

What is claimed is:

1. A high-power LED package comprising:
a thermally conductive substrate having a circuit board, a metal plate, a connecting member connected between said circuit board and said metal plate, and a plurality of through holes running through said circuit board and said metal plate;
a plurality of electric contact pins received in said through holes respectively and partially extending out of said through holes; and
at least one high-power LED mounted on said metal plate and electrically connected with said circuit board by means of a plurality of metal wires.

2. The high-power LED package as defined in claim 1, wherein said metal plate is a highly reflective aluminum substrate after vacuum electroplated.

3. The high-power LED package as defined in claim 1, wherein said connecting member is an adhesive disposed between a top side of said circuit board and a bottom side of said metal plate for closely connecting said circuit board and said metal plate.

4. The high-power LED package as defined in claim 1, wherein said through holes comprise first through holes and second through holes, said first through holes running through a top side of said metal plate and a bottom side of said circuit board, said second through holes running through a top side and the bottom side of said circuit board, said first and second through holes not corresponding to each other, each of said electric contact pins having a first contact portion and a second contact portion, said first contact portions being received in said first through holes respectively and being electrically connected with said at last one high-power LED by means of metal wires, said second contact portions being received in said second through holes being located in said second through holes respectively, said second contact portions each having an end extending out of said second through hole and exposed outside the bottom side of said circuit board, said second contact portions being electrically connected with said first contact portions.

5. The high-power LED package as defined in claim 1, wherein said connecting member comprises a plurality of rivets for fixedly connecting said circuit board and said metal plate.

6. The high-power LED package as defined in claim 1 further comprising a cover member mounted onto said metal plate, said cover member being covered on said metal plate for covering said at least one high-power LED and said metal wire.

7. The high-power LED package as defined in claim 6, wherein said cover member is a colloid made of silicone.

8. The high-power LED package as defined in claim 1, wherein said circuit board and said electric contact pins are connected by tin paste.

9. The high-power LED package as defined in claim 1 further comprising an insulated layer disposed between said metal plate and said circuit board.
